(19) United States
(12) Patent Application Publication
(10) Pub. No.: US 2009/0199064 A1
(43) Pub. Date: Aug. 6, 2009

(54) Corrupted packet toleration and correction system

(75) Inventors: Hayder Radha, East Lansing, MI (US); Shirish S. Karande, Santa Cruz, CA (US)

Correspondence Address: HARNESS, DICKEY & PIERCE, P.L.C., P.O. BOX 828, BLOOMFIELD HILLS, MI, 48303, US

(73) Assignee: Board of Trustees of Michigan State University, East Lansing, MI (US)

(21) Appl. No.: 11/920,189

(22) PCT Filed: May 11, 2006
(86) PCT No.: PCT/US06/18188

§ 371 Date: Jan. 5, 2009

Related U.S. Application Data
(60) Provisional application No. 60/679,960, filed on May 11, 2005.

(51) Int. Cl. H03M 13/05; G06F 11/10

(52) U.S. Cl. 714/752; 714/807; 714/E11.032

(57) ABSTRACT

A corrupted packet toleration and correction system includes a receiver adapted to employ a cross layer protocol that distinguishes between corrupted packets and error-free packets, and tolerates corrupted packets by making side information about corrupted packets available to an application layer. A decoder of the application layer provides hybrid decoding that simultaneously handles errors and erasures and takes advantage of the side information, including employing LDPC (HEEL) based codes over short packet blocks in the cross layer protocol.

### FIELD OF THE INVENTION

The present invention generally relates to a corrupted packet toleration and correction system, and more particularly to a system that employs a combination of Hybrid Error Erasure LDPC (HEEL) with a cross-layer approach.

### BACKGROUND OF THE INVENTION

Telecommunication networks typically employ protocols for transmitting packets between network nodes, with a receiver at a network node passing packets ultimately destined for that network node up to an application layer for decoding. Reed-Solomon (hereinafter “RS”) codes are typically employed for this purpose. Unlike conventional, non cross-layer, protocols, which usually drop all corrupted packets due to bit errors, cross-layer protocols (e.g., MAC-transport) and their corresponding “channels” exhibit both errors and erasures at their outputs. The nature of these errors and erasures is a function of the particular cross-layer scheme used.

It is well known that the erasure correcting capability of any code is much better than its ability to correct symmetric errors. Thus allowing the existence of corrupted packets at the application layer can lead to a reduction in throughput and channel capacity. However, if the number of errors in the corrupted packets is not large, then the total number of channel failures is reduced. This reduction in total number of failures can lead to an increase in channel capacity. Thus there is an inherent tradeoff between allowing and disallowing the relay of corrupted packets to the application layer. One pressing need is an identification of the channel conditions under which the existence of corrupted packets at the application layer can be preferred over dropping them entirely.

As the cross-layer protocols permit the occurrence of errors at the application layer, any Forward Error Correction scheme (hereinafter “FEC”) used in conjunction with these protocols must be capable of hybrid erasure and error recovery. Though Low-Density Parity Check (hereinafter “LDPC”) codes for channels with only errors and for channels with only erasures have been extensively studied, the design and performance of these codes in presence of erasures as well as errors is substantially unexplored. In addition, the usage of graph codes at the application layer has been limited to FEC designs for bulk-data transfer. Thus, another pressing need is an identification of the modifications required to be made to the LDPC decoding processes in order to enable them to perform hybrid erasure and error correction.

### SUMMARY OF THE INVENTION

In accordance with the present invention, a corrupted packet toleration and correction system includes a receiver adapted to employ a cross layer protocol that distinguishes between corrupted packets and error-free packets, and tolerates corrupted packets by making side information about corrupted packets available to an application layer. In another aspect of the present invention, a decoder of the application layer provides hybrid decoding that simultaneously handles errors and erasures and takes advantage of the side information, including employing Hybrid Error Erasure LDPC (hereinafter “HEEL”) based codes over short packet blocks in the cross layer protocol.

The combination of HEEL with a cross-layer approach according to the present invention is advantageous over previous corrupted packet toleration and correction systems because the conditional retention and use of the corrupted packets with side information at the application layer results in a dramatic increase in overall capacity. Further areas of applicability of the present invention will become apparent from the detailed description and drawings provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a diagrammatic view of a packet toleration and correction system according to the present invention;

FIG. 2 is a two-dimensional graph illustrating a comparison of channel capacity on the ordinate axis versus θ on the abscissa;

FIG. 3 is a two-dimensional graph illustrating εₘᵢₙ on the ordinate axis as a function of 1-δ on the abscissa;

FIG. 4 is a two-dimensional graph illustrating channel capacity for h=28 and d=512 bytes, with capacity on the ordinate axis versus θ on the abscissa;

FIG. 5 is a two-dimensional graph illustrating channel capacity for h=28 and d=512 bytes, with capacity on the ordinate axis versus θ on the abscissa;

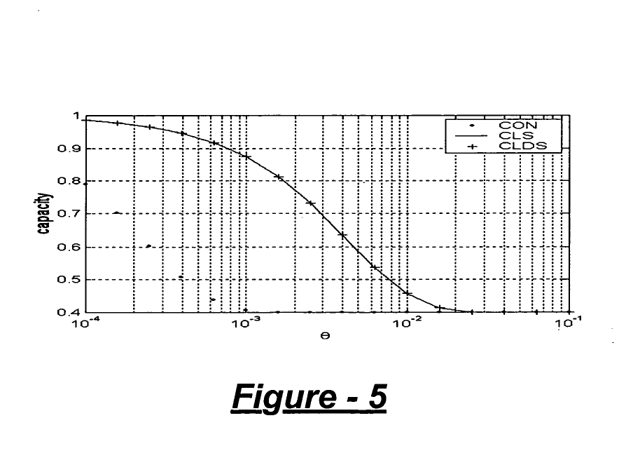

FIG. 6 is a two-dimensional graph illustrating packet throughput as a function of 1-δ, for λ=0.05, with throughput on the ordinate axis versus uncorrupted packets on the abscissa;

FIG. 7 is a two-dimensional graph illustrating packet throughput over severe channel conditions, with throughput on the ordinate axis and uncorrupted packets on the abscissa;

FIG. 8 is a two-dimensional graph illustrating a packet throughput comparison of cross-layer LDPC 100 according to the present invention with RS based FEC 102, with throughput on the ordinate axis and uncorrupted packets on the abscissa; and

FIG. 9 is a two-dimensional graph illustrating improvement in throughput due to side information, with throughput on the ordinate axis versus iterations on the abscissa.

### DETAILED DESCRIPTION OF THE PREFERRED EMBODIMENT

The following description of the preferred embodiment is merely exemplary in nature and is in no way intended to limit the invention, its application, or uses.

In order to keep the discussion generic and not dependent on a particular implementation or standard, the following discussions primarily consider three communication schemes: (a) transmission over erasure channels, which represents conventional transport and/or MAC protocols that do not forward corrupted packets to higher layers (e.g., due to bit errors not corrected by the physical layer); (b) transmission in presence of erasures and errors using a cross-layer design (hereinafter “CLD”), which is representative of cross-layer schemes that may pass corrupted packets to higher layers; and (c) side-information enhanced transmission in presence of erasures and errors using a cross-layer design (hereinafter “CLDS”).

The present teachings analyze the tradeoff involved in allowing corrupted packets to be relayed to the application layer. Channel conditions under which a cross-layer approach can provide improvement are identified. The capacity improvements are quantified, and it is established that dramatic increase in capacity can be achieved in many realistic scenarios by using a cross-layer approach. Moreover it is shown that, contrary to the conventional packet based schemes, HEEL based codes can be employed over short packet blocks in a cross-layer scenario. The decoding process is modified to provide hybrid decoding and also to take advantage of side information. Thus, the combination of HEEL with a cross-layer approach provides the best option among the considered schemes.

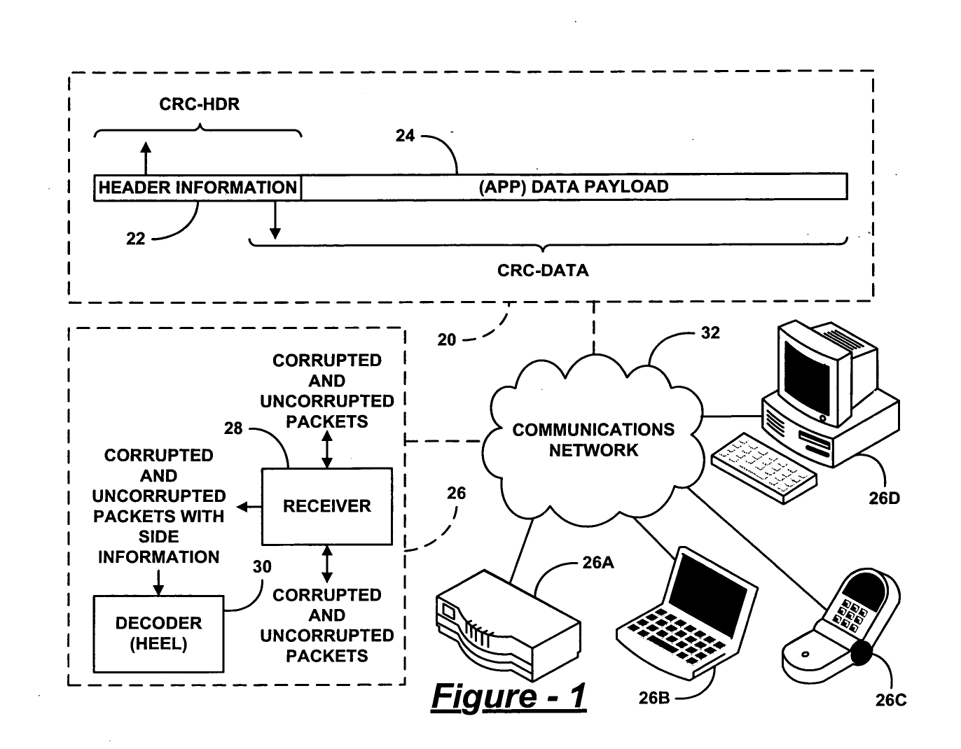

Referring to FIG. 1, the above schemes can be explained by considering a generic Logic Transmission Unit (hereinafter “LTU”) 20. The general packet structure can be segregated into two parts: 1) the header information 22; and 2) the data payload 24. In addition to traditional header information (e.g., nodes addresses), the LTU header information 22 contains two sets of check sums CRC-HDR and CRC-DATA. The CRC-HDR checksum is applied to and dependent on the header information 22 only; while the CRC-DATA check sum is applied to and dependent on the data payload 24 only. Hence, under this generic LTU model:
The conventional (non-cross layer) protocols drop (e.g., delete or lower) a packet of information if either of the checksums CRC-HDR, or CRC-DATA is not satisfied.
CLD, which represents protocols like UDP-lite, turns the CRC-DATA checksum off and drops the packet only if CRC-HDR is not satisfied. Therefore, a CLD channel exhibits both erasures (due to CRC-HDR violations) and possible errors in some of the delivered packets. It is important to note that (without further information or additional parity bits) the CLD channel receiver does not know which delivered packets are error-free and which packets are corrupted. It only distinguishes between erasures and delivered packets.
CLDS is a new alternative to the above schemes. Similar to CLD, a CLDS channel drops a packet of information only if CRC-HDR is not satisfied. However, in CLDS the CRC-DATA is not turned off but neither is the decision to drop a packet dependent on this checksum. Moreover, CRC-DATA and information about the success or failure of this check-sum is made available to the application layer as side information distinguishing between corrupted and uncorrupted packets. Therefore, unlike a CLD receiver of a network node, the CLDS receiver can distinguish corrupted packets from error-free packets.

Thus, the communication channels under consideration can be characterized as follows: (i) δ is the probability that at least a single bit is in error in the header and/or the data payload. Thus δ is the probability of a packet being dropped in a conventional (non-cross layer) protocol because at least one of the check sums, CRC-HDR and/or CRC-DATA, was not satisfied; (ii) λ is the probability that the packet header contains at least a single bit in error. Thus λ is the probability of packet being dropped in the cross-layer schemes because the check CRC-HDR was not satisfied. (Note that this event could occur regardless if there is an error within the packet data or not.) Thus δ−λ represents the probability of a corrupted packet being delivered to a CLD/CLDS channel receiver; (iii) ε is the conditional probability of a bit in the data payload being in error given that the checksum CRC-HDR is satisfied and checksum CRC-DATA has failed. Given a corrupted packet at a CLD/CLDS receiver, ε represents the probability of having a random bit selected from that packet to be in error. Thus the probability of bit error is given by (δ−λ)·ε. Let p be the conditional probability that a bit in an un-erased packet is in error. By definition of the above parameters it can be deduced that p=^{(δ-λ)·ε/(1-λ)}; (iv) For a cross-layer protocol with side-information (e.g., CLDS) let Z be a discrete random variable that takes on three possible outcomes: SZ {0, 1, ?}. Where, (i) Z=? if the header information 22 contains at least one single bit error and CLDS drops the packet. Thus, p(Z=?)=λ (ii) Z=0 if a packet contains no errors in the header information 22 but contains at least a single bit error in the data payload 24. Thus, p(Z=0)=(δ−λ) and (iii) Z=1 if neither the header information 22 nor the data payload 24 contain even a single erroneous bit. Thus, p(Z=1)=(1−δ).

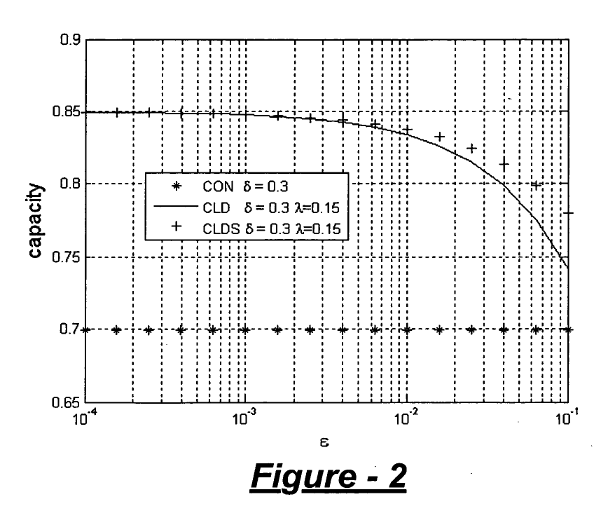

Turning now to FIG. 2, a channel capacity based evaluation reveals the efficacy of the cross layer approach combined with HEEL. The channel capacities of the above described channels can be expressed as:
It is well known that the channel capacity of a BEC is given by 1−δ, thus capacity of a conventional protocol is given by

C_{CON}=1−δ (1)
The cross-layer channel can be represented as a cascade of a BEC channel with probability of erasure equal to λ followed by a Binary Symmetric Channel (hereinafter “BSC”) with probability of bit error equal to p. It can be easily shown that the channel capacity of such a cascade is given by the product of the channel capacities of the individual channels:

C_{CLD}=(1−λ)·(1−h_{b}(p)) (2)
The channel capacity of the cross-layer channel in presence of side information Z is as follows: when Z=1 all the bits are transmitted reliably and conditional capacity is 1; when Z=? all the bits get erased and conditional capacity is 0 while when Z=0 the channel reduces to BSC with cross-over probability e and conditional capacity is (1−h_{b}(ε)). Thus the channel capacity of CLDS is given by

C_{CLDS}=(1−δ)+(δ−λ)·(1−h_{b}(ε)) (3)

FIG. 2 shows a comparison of the channel capacities offered by the three protocols considered above. It can be clearly seen that the cross-layer protocols can provide dramatic improvements in capacity. Moreover it should be noted that under severe channel conditions, the side-information available on account of the CRC's can be very useful.

Thus in order to clearly establish the channel parameters under which a particular protocol offers better performance, a couple of lemma's are proven immediately below.

Lemma 1: C_{CON}>C_{CLD} [symbol] h_{b}(p)>(p/ε),

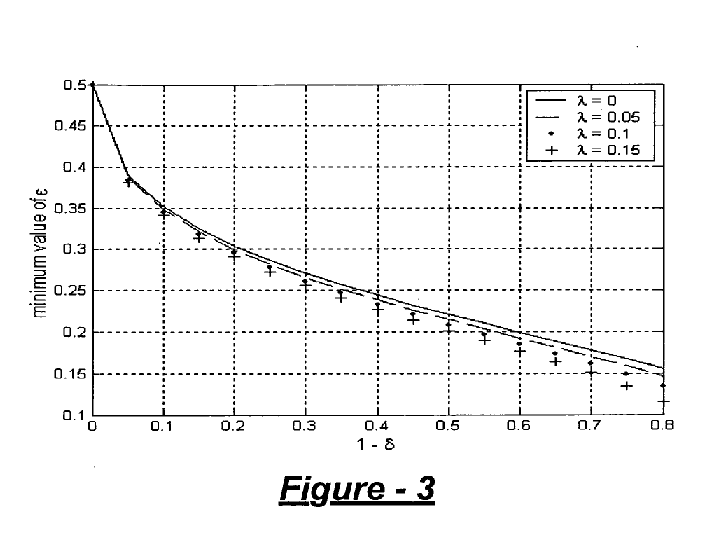

Lemma 1 tells us that for a given δ,λ there exists a threshold εₘᵢₙ such that if the level of corruption in the corrupted (but not dropped) packets is greater than this threshold then the conventional schemes shall perform better than the cross-layer scheme. Thus εₘᵢₙ divides the parameter space into two separate regions and thus demarcates the region over which cross-layer schemes can perform better than the conventional scheme. In FIG. 3, εₘᵢₙ is plotted as a function of 1−δ for different parameter values of λ.

Lemma 2: a) C_{CLDS}≧C_{CON} with equality occurring iff ε=0.5 or δ=λ. (b)C_{CLDS}≧C_{CLD} with equality occurring iff δ=λ.

Proof:

a) Since (δ−λ)·(1−h_{b}(ε))≧0. Equality occurs iff (δ−λ)·(1−h_{b}(ε))=0, i.e. iff δ=λ or h_{b}(ε)=1 i.e. ε=0.5.

b) This result can be proved by using the following fact: If f(x) is strictly monotonically decreasing over [a,b] then

$$∀ a , β ∈ [ a , b ] , a , β \neq 0 , a < β ⇒ \frac{f ( a )}{a} > \frac{f ( β )}{β} .$$

Notice that h_{b}(x) is strictly monotonically decreasing for ∀xε[0,1]. As 1−λ≧1−δ it can be shown that p≦ε, which implies

$$\frac{{h}_{b} ( p )}{p} \geq \frac{{h}_{b} ( ɛ )}{ɛ} .$$

Substituting for p we can conclude that (1−δ)+(δ−λ)·(1−h_{b}(ε))≧(1−λ)·(1−h_{b}(p)). Note that equality can occur only when p=ε, which is possible iff δ=1. Thus the capacity of the CLDS scheme is provably better than both CLD and CON.

$$\begin{matrix}{C}_{CON ( n - hop )} = {\prod }_{i = 1}^{n} ( 1 - {δ}_{i} ) & ( 4 ) \\ {C}_{CLD ( n - hop )} = ( {\prod }_{i = 1}^{n} ( 1 - {λ}_{i} ) ) \cdot ( 1 - {h}_{b} ( {{*}^{n}}_{i = 1} {p}_{i} ) ) & ( 5 )\end{matrix}$$

note: a*b=a·(1−b)+b·(1−a) by definition
note: the operator “*” is s.t. p₁*p₂=p₁·(1−p₂)+p₂·(1−p₁) and

$${{*}^{n}}_{i = 1} {p}_{i} = ( {p}_{1} * {p}_{2} ) * {p}_{3} ) … ) * {p}_{i} ) … ) * {p}_{n} ) \cdot {C}_{CLDS ( n - hop )} = ( {\prod }_{i = 1}^{n} ( 1 - {δ}_{i} ) ) + ( {\prod }_{i = 1}^{n} ( 1 - {λ}_{i} ) ) \cdot ( 1 - {h}_{b} ( ( \frac{( {\prod }_{i = 1}^{n} ( 1 - {λ}_{i} ) )}{( {\prod }_{i = 1}^{n} ( 1 - {λ}_{i} ) ) - ( {\prod }_{i = 1}^{n} ( 1 - {δ}_{i} ) )} ) \cdot ( {{*}^{n}}_{i = 1} {p}_{i} ) ) ) \qquad ( 6 )$$

The term “multi-hop” is used to refer to microwave links requiring two or more links to get to a destination, which allows a link to extend distance, as well as move the link path around buildings or mountains. Thus, a multi-hop wireless channel can be represented as a cascade of channels. For example, the conventional scheme can be represented by a cascade of BEC channels, where each link is represented by a distinct BEC channel in the cascade. Similar cascades can be made for the cross-layer schemes too. Thus expressions for channel capacities over multiple hops are given by equations (4), (5), (6). Results for multiple-hops in FIG. 2 are obtained by assuming an identical channel for each hop. FIG. 2 shows that the capacity of a cross layer scheme even over multiple hops can be better than that of a conventional scheme over a single hop.

The following substitutions in equations (4), (5), (6) convert them into equations (1), (2), (3) respectively. Thus it is sufficient to maintain the discussion in terms of δ, λ, p, ε from here on. Transmission over multiple-hops can be represented by higher error/erasure values.

$$Let λ = 1 - {\prod }_{i = 1}^{n} ( 1 - {λ}_{i} )$$

$$and$$

$$p = ( {{*}^{n}}_{i = 1} {p}_{i} )$$

$$also$$

$$let δ = 1 - {\prod }_{i = 1}^{n} ( 1 - {δ}_{i} )$$

$$and$$

$$ɛ = ( \frac{1 - λ}{δ - λ} ) \cdot p$$

Before proceeding further, it is prudent to pay some attention to dependence of the aforementioned parameters on the link-layer channel. These parameters, δ,λ,ε are parameterized below; however these parameters are not actually independent of each other and are in fact a function of the underlying link-layer channel. Assuming a specific link-layer channel can indeed lead to more precise conclusions and render some of the regions (combination of δ,λ,p) described below unachievable. However, parameterizing the channels as below allows conductance of a more generalized analysis and, whenever necessary, δ,λ,p can be expressed in terms of the under-lying channel to derive more precise expressions. Further below, an example of such analysis is provided. However, the remainder of the present teachings continue to assume that δ,λ,ε are independent.

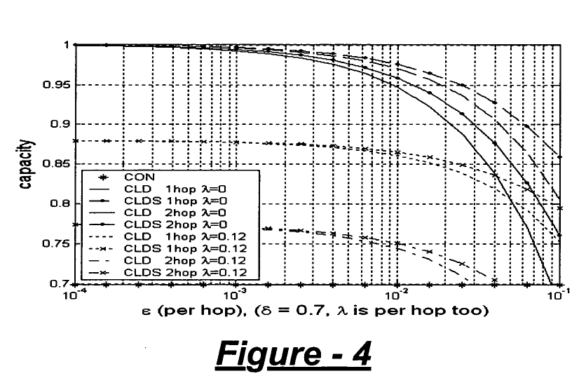

Let the h and d represent the number of header and payload bits respectively. If the link-layer channel is assumed to be a BSC channel with cross-over probability q then it can be said that δ=1−(1−q)^{(h+d)},λ=1−(1−q)^{h} and ε=q. Thus, the channel capacities are given by C_{CON}=(1−q)^{(h+d)},C_{CLD}=(1−q)^{h}·(1−h_{b}((1−(1−q)^{d})·q)), and C_{CLDS}=(1−q)^{h}·(1−((1−(1−q)^{d})·h_{b}(q))). FIG. 4 shows the performance comparison of the three schemes for header and payload sizes typical to the wireless LAN.

Lemma 3: ∀qε(0,0.5), ∃dₘᵢₙ≧0 s.t, d≧dₘᵢₙ [symbol] C_{CLD}≧C_{CON} [symbol] equality occurs iff d=dₘᵢₙ.

Note: (1−(1−q)^{d})≧h_{b}((1−(1−q)^{d})·q) [symbol] C_{CLD}≧C_{CON}

The above lemma can be proved by showing that the equation (1−(1−q)^{d})=h_{b}((1−(1−q)^{d})·q) can at maximum have a single non-negative solution dₛₒₗ. Moreover it should be observed that lim h_{b}((1−(1−q)^{d})·q)=h_{b}(q) which is less than ^{d→∞}lim (1−(1−q)^{d})=1∀qε (0,0.5). Thus if a solution to the above equation does not exist, it can be concluded that C_{CLD}≧C_{CON}, while if a solution does exist then ∃d>dₛₒₗs.t.(1−(1−q)^{d})>h_{b}((1−(1−q)^{d})·q). This statement proves the above lema. The value of dₘᵢₙ, even for q=0.4, is less than 20 bytes. Thus, if the link-layer channel resembles a BSC, the CLD scheme is better than CON almost always.

The deduction made above can be generalized by considering a channel over which all the packet transmissions are not necessarily susceptible to errors. Such a behavior is possible on time-varying channels and over wireless networks with dynamic topologies. Thus, consider a channel over which only a fraction η number of the total transmitted packets are susceptible to errors. When packet transmissions are susceptible to errors, the behavior of the link-layer channel can be assumed to be equivalent to a BSC with crossover probability of θ. For such a channel it can be shown that ε=θ,δ=η−(1−θ)^{(h+d)} and λ=η−(1−θ)^{h}. Thus it can be shown that the channel capacities of the three schemes are

$$\begin{matrix}{C}_{CON} = 1 - η + {( 1 - θ )}^{( h + d )} & ( 7 ) \\ {C}_{CLD} = ( \begin{matrix}1 - η + \\ {( 1 - θ )}^{h}\end{matrix} ) \cdot ( 1 - {h}_{b} ( \frac{{( 1 - θ )}^{h} \cdot ( 1 - {( 1 - θ )}^{d} ) \cdot θ}{1 - η + {( 1 - θ )}^{h}} ) ) & ( 8 ) \\ {C}_{CLD} = ( \begin{matrix}( 1 - η + {( 1 - θ )}^{( h + d )} ) + \\ {( 1 - θ )}^{h} \cdot ( 1 - {( 1 - θ )}^{d} ) \cdot ( 1 - {h}_{b} ( θ ) )\end{matrix} ) & ( 9 )\end{matrix}$$

It should be observed that the expressions for the BSC example can be obtained from the above equations by setting η=1.

Thus it is again evident that a cross-layer approach can provide significant improvements in capacity. The examples considered above predict that it is not possible to achieve throughput improvements on account of a cross-layer channel when the number of errors in a packet is greater than 1%. Limitation of an analysis based on a specific link-layer channel model should be noted.

LDPC based FEC performance is analyzed below. Though LDPC (and other similar graph codes) codes have been extensively employed for a variety of channels, their usage at the application layer over computer networks has been limited. The current FEC schemes treat an entire packet as a single symbol. Since an efficient design of a sparse graph code requires the length of the codeword to be large, FEC blocks at the application layer also have to include a large number of packets to provide good performance. Thus the research at the application layer has primarily concentrated on design of efficient codes for transfer of bulk data. The advantage of using a symbol of size smaller than the entire packet is minimal, if the channel failures consist only of burst erasures on account of packet drops. However, in a cross-layer scenario a significant advantage can be gained by employing a code based on a smaller symbol size.

Accordingly, all the LDPC based FEC simulations discussed here combine all the bits in a single packet block to form a single codeword. Thus, a single (61440, 40960) LDPC code is used in the simulations discussed herein. A packet block-length of 30 is employed, and therefore each packet is 256 bytes long. After encoding, the bits in the codeword are remapped in such a way that the packet level FEC is systematic. The packet block is systematic and includes 20 message packets and 10 redundant packets. The maximum number of iterations is maintained to be 25, and stopping criteria checking for a codeword at the end of each iteration are used; thus, undetected decoding errors are avoided.

The same graph structure is chosen for all codes below. The emphasis of the discussion here is on the decoding procedure and the relative performance under different protocol schemes. Thus, a regular LDPC code is used with 3 checks per message bit.

On occurrence of a block decoding failure, the channel decoder is unable to recover all the dropped/corrupted packets. However as the FEC block is systematic, message packets that can be identified as uncorrupted can still be forwarded to the eventual application. However, in a cross layer design like CLD, information about CRC-DATA is not available if a decoding failure is encountered; an FEC implementation on CLD drops the entire packet block.

Returning to FIG. 1, HEEL is discussed in further detail. The corrupted packet toleration and correction system 26 according to the present invention includes a receiver 28 and decoder 30. System 26 can be any network node, such as a router 26A, laptop computer 26B, cell phone 26C, desktop computer 26D, or other device connected to communications system 32, such as the Internet, an intranet, extranet, ad hoc network, and other types of networks. In a preferred embodiment, receiver 28 of a network node receives corrupted and uncorrupted packets from upstream (and may also transmits them downstream in some embodiments) only dropping a packet if the CRC-HDR check fails, but leaving the CRC-DATA on. Packets received from upstream and ultimately destined for the network node are passed up to decoder 30 of the application layer with side information about the results of the CRC-DATA check.

The LDPC decoding process used in conjunction with the conventional scheme is a simple bit—flipping process. However, the decoding process used in conjunction with the cross-layer protocols in the preferred embodiment is required to handle simultaneous decoding of errors and erasures. Yet, as the messages passed in the LDEE decoding process can take only three possible values; the decoding capability of these codes is compromised. Thus, a decoding process HEEL is employed by decoder 30, which is based on a belief propagation technique, and which does not constrain the messages passed along the graph edges to a few finite discrete values as in prior studies. In such prior studies, the erasures are handled in a special way by always keeping them undecided about being a 0/1. However, there is no need to treat the erasure as a special symbol when used along with belief propagation. Thus, HEEL uses the sum-product process for simultaneous correction of erasures as well as errors by setting all the erased bits to 0 and setting the a priori probability of the erased bit being in error to 0.5.

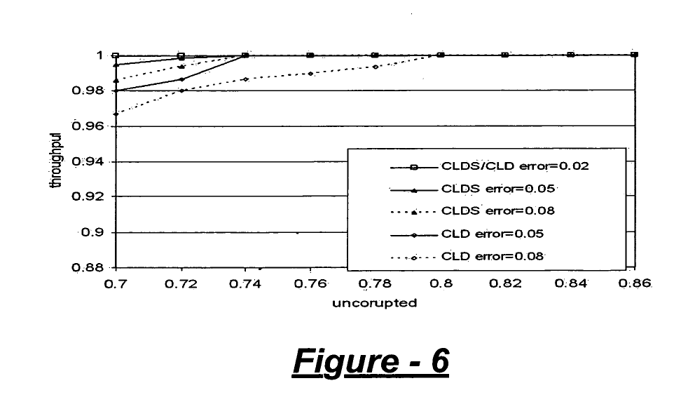

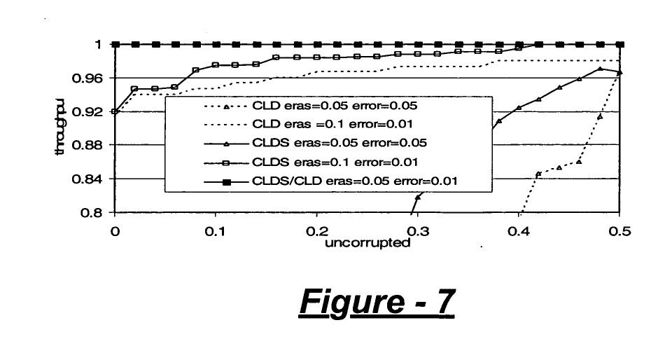

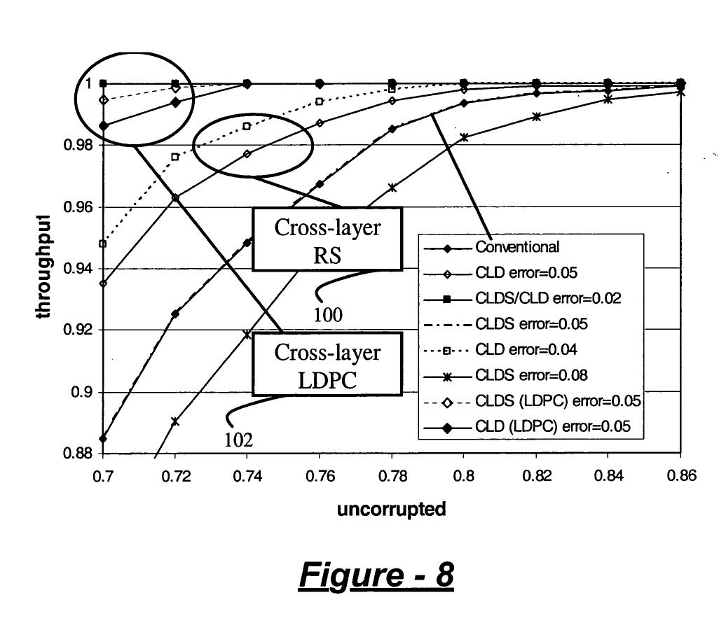

FIG. 6 shows the performance of the cross-layer protocols relative to a traditional protocol for non-severe channel conditions. If the number of errors is less than 1-2%, the cross-layer schemes can guarantee reliable transmission. The FEC performance over conventional protocols drops drastically as the value of δ increases. Thus, the advantage of using a cross-layer protocol significantly increases as the value of δ increases, giving a throughput improvement of at least 10% under a variety of realistic channel conditions. Moreover, as shown by FIG. 7, cross-layer protocols can maintain very good packet throughput even under severe channel conditions, and the performance drops only when the number of bit errors per packet are very high. Comparing the results shown by FIG. 8 with those shown by FIG. 7 clearly illustrates the advantage of using HEEL over an RS based scheme. RS have been the codes of choice for FEC schemes for real-time application; however, over cross-layer channels, the choice should clearly be in favor of LDPC.

Side-information for improved decoding efficiency is discussed as follows. In FIGS. 7 and 8, it can be seen that the FEC performance over CLDS is always better than that on CLD. This difference can be attributed to two factors: (a) a better handling of FEC block decoding failure; and (2) because the HEEL decoding process used for CLDS is modified to take advantage of the side information provided by CRC-DATA. If the CRC-DATA of a particular packet is satisfied, than the a priori probability of the bits in this packet being in error is set to 0. Thus, the iterative decoding process does not change the value of the bits that have already been received correctly. Even when the decoding process does not converge to a codeword, it is possible for the decoding to correct some errors; and, hence, the packets that were initially corrupted but are rendered error free after FEC decoding by updating the CRC-DATA checksum are identified.

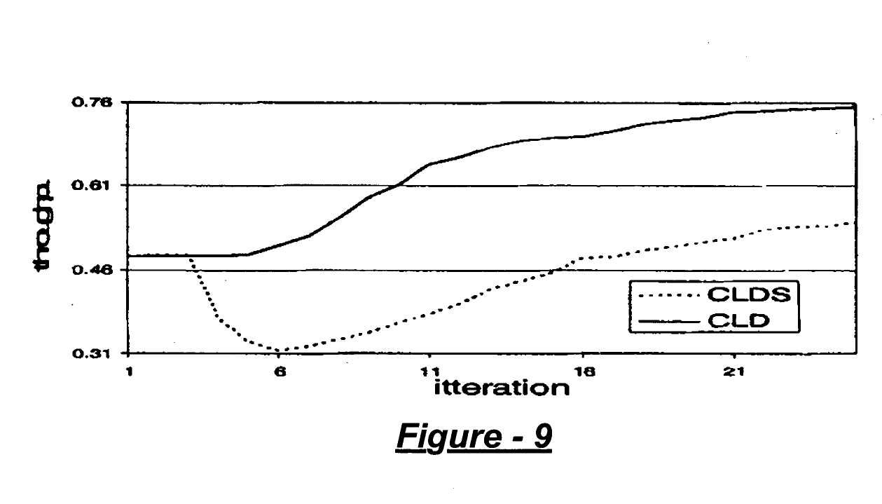

FIG. 9 identifies the precise effect of using such side information. As CLD has no information about error localization, it initially corrupts more bits than corrects them. Though the HEEL process is able to recover from such a “dip”, under severe channel conditions, it takes too many iterations to make a substantial recovery and, at times, it is impossible to completely recover. Thus, the performance of CLDS is better than CLD, especially under severe channel conditions.

The present teachings analyze the tradeoff involved in allowing corrupted packets to be relayed to the application layer. Channel conditions under which a cross-layer approach can provide improvement are identified. The capacity improvements are quantified, and it is established that dramatic increase in capacity can be achieved in many realistic scenarios by using a cross-layer approach. Moreover it is shown that, contrary to the conventional packet based schemes, LDPC (HEEL) based codes can be employed over short packet blocks in a cross-layer scenario. The decoding process is adapted to provide hybrid decoding and also to take advantage of side information. Thus it is shown that the combination of HEEL with a cross-layer approach provides the best option among the considered schemes.

In some embodiments, a number of packet header updates is determined and recorded in a header field of the packet header. For example, packet checksums (i.e., CK-DATA) are recalculated at each hop taken by a packet in a communication network, and the packet checksums are updated at each of the hops. Storing a count of checksum updates in the header field in the packet header of the packet over multiple hops ensures that this information is available for use by an end receiver to determine corruption status of the packet payload. For example, the end receiver can access the packet header of the packet received over the communications network and read the header field of the packet header to determine the number of checksum updates. Then, the end receiver can use the number of checksum updates to determine corruption status of the payload of the packet. For example, let n=number of updates: Use n in one or more of the following ways:

1) Incorporate an application dependent threshold t such that if n is greater than a threshold t just drop the packet;
2) Again in certain scenarios the average bit error-rate ε over each hop is constant and with each packet we can associate a cumulative bit error rate

$$c = \frac{1 - {( 1 - 2 ɛ )}^{number of update}}{2} .$$

This error rate c is used in the LDPC/sum-product/HEEL decoding.
   The usage of n is not limited to the above methods.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. A corrupted packet toleration and correction system, comprising:
a receiver adapted to employ a cross layer protocol operable to distinguish between corrupted packets of information and error-free packets, and tolerate corrupted packets by making side information about corrupted packets available to an application layer; and
a decoder of the application layer adapted to provide hybrid decoding that handles errors and erasures based on the side information by employing Low-Density Parity Check (LDPC) based codes over short packet blocks in the cross layer protocol.

2. The system of claim 1, wherein said receiver is adapted to drop a packet comprising header information and data payload only if a CRC-HDR checksum fails, while leaving a CRC-DATA checksum on, wherein the CRC-HDR checksum is applied to and dependent on the header information only, while the CRC-DATA check sum is applied to and dependent on the data payload only.

3. The system of claim 2, wherein said receiver is adapted to determine whether to drop the packet independently of the CRC-DATA checksum.

4. The system of claim 2, wherein said receiver is adapted to make the CRC-DATA and information about success or failure of this check-sum available to the application layer as the side information.

5. The system of claim 1, wherein said receiver is adapted to make a checksum and information about success or failure of this checksum available to the application layer as the side information.

6. The system of claim 5, wherein said receiver is adapted to determine whether to drop a packet independently of the checksum.

7. The system of claim 5, wherein said checksum is at least partially payload dependent.

8. The system of claim 1, wherein said decoder employs a decoding process that is based on a belief propagation technique, and which does not constrain messages passed along graph edges to three or less finite discrete values, and does not treat an erasure as a special symbol.

9. The system of claim 1, wherein said decoder uses a sum-product process accomplishing simultaneous correction of erasures as well as errors by setting all erased bits to zero and setting a probability of erased bits being in error to substantially one-half.

10. A receiver comprising a packet processing module adapted to employ a cross layer protocol operable to distinguish between corrupted packets of information and error-free packets, and tolerates corrupted packets by making side information about corrupted packets available to an application layer.

11. The receiver of claim 10, wherein said receiver is adapted to drop a packet comprising header information and data payload only if a CRC-HDR checksum fails, while leaving a CRC-DATA checksum on, wherein the CRC-HDR checksum is applied to and dependent on the header information only, while the CRC-DATA check sum is applied to and dependent on the data payload only.

12. The receiver of claim 11, wherein said receiver is adapted to determine whether to drop the packet independently of the CRC-DATA checksum.

13. The receiver of claim 11, wherein said receiver is adapted to make the CRC-DATA and information about success or failure of this check-sum available to the application layer as the side information.

14. The receiver of claim 10, wherein said receiver is adapted to make a checksum and information about success or failure of this checksum available to the application layer as the side information.

15. The receiver of claim 14, wherein said receiver is adapted to determine whether to drop a packet independently of the checksum.

16. The receiver of claim 14, wherein said checksum is at least partially payload dependent.

17. A decoder comprising a decoding process module adapted to receive side information distinguishing corrupted packets from uncorrupted packets, and provide hybrid decoding that handles errors and erasures based on the side information by employing Low-Density Parity Check (LDPC) based codes over short packet blocks in a cross layer protocol.

18. The decoder of claim 17, wherein said decoder employs a decoding process that is based on a belief propagation technique, which does not constrain messages passed along graph edges to three or less finite discrete values, and does not treat an erasure as a special symbol.

19. The decoder of claim 17, wherein said decoder uses a sum-product process accomplishing simultaneous correction of erasures as well as errors by setting all erased bits to zero and setting an a priori probability of erased bits being in error to one-half.

20. A corrupted packet toleration and correction method, comprising:
distinguishing between corrupted packets and error free packets with a cross-layer protocol;
tolerating corrupted packets by making side information about corrupted packets available to an application layer; and
performing hybrid decoding at the application layer, including handling errors and erasures based on the side information by employing Low-Density Parity Check (LDPC) based codes over short packet blocks in the cross layer protocol.

21. The method of claim 20, further comprising dropping a packet comprising header information and data payload only if a CRC-HDR checksum fails, while leaving a CRC-DATA checksum on, wherein the CRC-HDR checksum is applied to and dependent on the header information only, while the CRC-DATA check sum is applied to and dependent on the data payload only.

22. The method of claim 21, further comprising determining whether to drop the packet independently of the CRC-DATA checksum.

23. The method of claim 21, further comprising making the CRC-DATA and information about success or failure of this check-sum available to the application layer as the side information.

24. The method of claim 20, further comprising making a checksum and information about success or failure of this checksum available to the application layer as the side information.

25. The method claim 24, further comprising determining whether to drop a packet independently of the checksum.

26. The method of claim 24, wherein said checksum is at least partially payload dependent.

27. The method of claim 20, further comprising employing a decoding process that is based on a belief propagation technique, and which does not constrain messages passed along graph edges to three or less finite discrete values, and does not treat an erasure as a special symbol.

28. The method of claim 20, further comprising using a sum-product process accomplishing simultaneous correction of erasures as well as errors by setting all erased bits to zero and setting an a priori probability of erased bits being in error to one-half.

29. A method for tolerating corrupted packets, comprising employing a cross layer protocol that distinguishes between corrupted packets and error-free packets, and tolerates corrupted packets by making side information about corrupted packets available to an application layer.

30. The method of claim 29, further comprising dropping a packet comprising header information and data payload only if a CRC-HDR checksum fails, while leaving a CRC-DATA checksum on, wherein the CRC-HDR checksum is applied to and dependent on the header information only, while the CRC-DATA check sum is applied to and dependent on the data payload only.

31. The method of claim 30, further comprising determining whether to drop the packet independently of the CRC-DATA checksum.

32. The method of claim 30, further comprising making the CRC-DATA and information about success or failure of this check-sum available to the application layer as the side information.

33. The method of claim 29, further comprising making a checksum and information about success or failure of this checksum available to the application layer as the side information.

34. The method of claim 33, determining whether to drop a packet independently of the checksum.

35. The method of claim 33, wherein said checksum is at least partially payload dependent.

36. A decoding method, comprising:
receiving side information distinguishing corrupted packets from uncorrupted packets;
performing hybrid decoding that handles errors and erasures based on the side information; and
employing Low-Density Parity Check (LDPC) based codes over short packet blocks in a cross layer protocol.

37. The method of claim 36, further comprising employing a decoding process that is based on a belief propagation technique, which does not constrain messages passed along graph edges to three or less finite discrete values, and does not treat an erasure as a special symbol.

38. The method of claim 37, further comprising using a sum-product process accomplishing simultaneous correction of erasures as well as errors by setting all erased bits to zero and setting an a priori probability of erased bits being in error to one-half.

39. A method of approximating channel conditions in a given network infrastructure in order to design a corrupt packet toleration system, the method comprising:
determining δ as a probability that at least a single bit is in error in any one of a packet header and a data payload of the packet, thus determining δ as a probability of the packet being dropped in a conventional (non-cross layer) protocol because at least one of two check sums, CRC-HDR and/or CRC-DATA, of the packet not being satisfied;
determining λ as a probability that the packet header contains at least a single bit in error, thus determining λ as a probability of the packet being dropped in a cross-layer scheme because the check CRC-HDR was not satisfied;
determining ε as a conditional probability of a bit in the data payload being in error given that the checksum CRC-HDR is satisfied and checksum CRC-DATA has failed; and
performing a channel capacity evaluation of at least two communication schemes.

40. The method of claim 39, further comprising performing evaluation of channel capacity resulting from use of at least the following communication schemes: (a) transmission over erasure channels, which represents conventional transport or MAC protocols (CON) that do not forward corrupted packets to higher layers; (b) transmission in presence of erasures and errors using a cross-layer design (CLD), which is representative of cross-layer schemes that conditionally pass corrupted packets to higher layers; and (c) side-information enhanced transmission in presence of erasures and errors using a cross-layer design (CLDS).

41. The method of claim 40, further comprising evaluating channel capacity of the conventional protocol as:
C_{CON}=1−δ.

42. The method of claim 40, further comprising:
representing a cross-layer channel as a cascade of a BEC channel with probability of erasure equal to λ followed by a Binary Symmetric Channel (BSC) with probability of bit error equal to p; and
evaluating channel capacity of the cascade as a product of channel capacities of individual channels according to:
C_{CLD}=(1−λ)·(1−h_{b}(p)).

43. The method of claim 40, further comprising evaluating channel capacity of CLDS according to:
C_{CLDS}=(1−δ)+(δ−λ)·(1h_{b}(ε)).

44. The method of claim 40, further comprising:
evaluating channel capacity of the CON according to:
$${C}_{CON ( n - hop )} = {\prod }_{i = 1}^{n} ( 1 - {δ}_{i } ) ;$$
evaluating channel capacity of the CLD according to:
$${C}_{CLD ( n - hop )} = ( {\prod }_{i = 1}^{n} ( 1 - {λ}_{i} ) ) \cdot ( 1 - {h}_{b} ( {{*}^{n}}_{i = 1} {p}_{i} ) ) ;$$
and
evaluating channel capacity of the CLDS according to:
$${C}_{CLDS ( n - hop )} = ( {\prod }_{i = 1}^{n} ( 1 - {δ}_{i} ) ) + ( {\prod }_{i = 1}^{n} ( 1 - {λ}_{i} ) ) \cdot ( 1 - {h}_{b} ( ( \frac{( {\prod }_{i = 1}^{n} ( 1 - {λ}_{i} ) )}{( {\prod }_{i = 1}^{n} ( 1 - {λ}_{i} ) ) - ( {\prod }_{i = 1}^{n} ( 1 - {δ}_{i} ) )} ) \cdot ( {{*}^{n}}_{i = 1} {p}_{i} ) ) ) .$$

45. The method of claim 40, further comprising evaluating the channel capacity of the three schemes according to:
$${C}_{CON} = 1 - η + {( 1 - θ )}^{( h + d )} ;$$
$${C}_{CLD} = ( \begin{matrix}1 - η + \\ {( 1 - θ )}^{h}\end{matrix} ) \cdot ( 1 - {h}_{b} ( \frac{{( 1 - θ )}^{h} \cdot ( 1 - {( 1 - θ )}^{d} ) \cdot θ}{1 - η + {( 1 - θ )}^{h}} ) ) ;$$
$$and$$
$${C}_{CLD} = ( \begin{matrix}( 1 - η + {( 1 - θ )}^{( h + d )} ) + \\ {( 1 - θ )}^{h} \cdot ( 1 - {( 1 - θ )}^{d} ) \cdot ( 1 - {h}_{b} ( θ ) )\end{matrix} ) .$$

46. A method of determining and recording a number of packet header updates in a communication network;
recalculating packet checksums at each hop taken by a packet in the communication network;
updating the packet checksums at each of the hops; and
storing a count of checksum updates in a header field in a packet header of the packet over multiple hops.

47. A method of determining corruption status of a payload of a packet at a receiver in a communications network, the method comprising:
accessing a packet header of a packet received over a communications network;
reading a header field of the packet header to determine a number of checksum updates occurring as a result of recalculation of checksums of the packet at each hop taken by the packet in the communications network, update of the packet checksums at each of the hops, and storage of a count of checksum updates in the header field of the packet header of the packet over multiple hops; and
using the number of checksum updates to determine corruption status of a payload of the packet.

48. The method of claim 47, further comprising making a comparison between the number of checksum updates and a predetermined threshold and deciding whether to drop the packet based on results of the comparison.

49. The method of claim 47, further comprising:
associating with each packet a cumulative bit error rate
$$c = \frac{1 - {( 1 - 2 ɛ )}^{number of update}}{2} ;$$
and
using c is used in a decoding process.

50. A communication network, comprising:
network nodes recalculating packet checksums at each hop taken by a packet in the communication network, updating the packet checksums at each of the hops, and storing a count of checksum updates in a header field in a packet header of the packet over multiple hops; and
a receiver using the number of checksum updates to determine corruption status of a payload of the packet.

51. The communication network of claim 50, wherein said receiver makes a comparison between the number of checksum updates and a predetermined threshold and decides whether to drop the packet based on results of the comparison.

52. The communication network of claim 50, wherein said receiver associates with each packet a cumulative bit error rate
$$c = \frac{1 - {( 1 - 2 ɛ )}^{number of update}}{2} ,$$
and uses c in a decoding process.
